(19) United States
(12) Patent Application Publication
(10) Pub. No.: US 2007/0047606 A1
(43) Pub. Date: Mar. 1, 2007

(54) Edge emitting semiconductor laser with short gain region

(76) Inventors: Daniel A. Francis, Oakland, CA (US); Ashish K. Verma, San Jose, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/215,695

(22) Filed: Aug. 30, 2005

(51) Int. Cl. H01S 5/00

(52) U.S. Cl. 372/45.01

(57) ABSTRACT

Systems and methods for short length gain regions in edge emitting lasers. After forming the lower layers of a laser on a substrate, the active layer is formed. The active layer is then selectively etched. The unetched portion of the active layer corresponds to an active region of the laser. The etched portions are then selectively regrown with a material that is transparent to light emitted by the active region. The active layer thus includes an active region and an inactive region. Next, the upper layers are grown or formed over the active layer. Selective regrowth of the active layer enables a length of the active region to be independent of the cleaved length of the laser. This reduces current and power requirements of the laser.

### RELATED APPLICATIONS

Not applicable.

### BACKGROUND OF THE INVENTION

1. The Field of the Invention

The present invention relates to the field of semiconductor lasers. More particularly, embodiments of the invention relate to the field of edge emitting semiconductor lasers with short gain regions.

2. The Relevant Technology

In fiber optic communications, a transducer is typically present at the end of the fiber optic links. These transducers, often referred to as transceivers, convert optical signals to electrical signals and electrical signals to optical signals. To successfully convert an electrical signal into an optical signal, the transceivers require a light source of some type. The light emitted by the light source is then modulated to carry data over optic links.

Semiconductor lasers are prime examples of light sources used in transceivers and they come in a variety of different types. One type of semiconductor laser is an edge emitting laser. Fabry-Perot lasers, distributed feedback (DFB) lasers, and distributed Bragg reflector (DBR) lasers are each examples of edge emitting lasers and each of these lasers has various advantages.

Fabry-Perot lasers, for example, are less expensive to manufacture than DFB lasers and DBR lasers. However, the optical emission of Fabry-Perot lasers has a wide spectral width when compared to DFB and DBR lasers. In other words, the laser cavity of a Fabry-Perot laser can support multiple wavelengths, all of which may be emitted by the Fabry-Perot laser. The wide spectral band of Fabry-Perot lasers can lead, for example, to problems such as dispersion, which limits the bandwidth of the optical fiber. While DFB lasers and DBR lasers have a much narrower spectral width than common Fabry-Perot lasers, they are also more expensive.

One of the problems associated with Fabry-Perot lasers, as well as other types of edge emitting lasers, is that the length of the laser cavity is relatively long. Unfortunately, the long length of the laser cavity is related to the inability to cleave the laser in short lengths. In other words, there is a limit as to how small of a laser bar can be handled and successfully cleaved. In addition, the actual cleavage plane may not be known. As a result, the length of the laser cavity is typically the same as the length of the laser itself after cleaving.

Because the length of the laser cavity is not independent of the laser length, there is a corresponding price to be paid in terms of threshold current. The laser is typically pumped along its length in order to achieve stimulated emission. As a result, the length of the laser cavity has an impact on the threshold current and also on the differential efficiency as measured by light out versus current.

The power requirements of a given system are limited by the power consumed by the laser. The need to pump current along the entire length of the active region therefore has a corresponding cost in power. If the length of the active region could be reduced, then there would be a corresponding reduction in laser power and system power. Cleaving the device is one potential solution to these problems, but as previously stated, it is often difficult to achieve shorter cleaving distances. As a result, the cleaving process limits the ability to both reduce the power consumption of the laser and also impacts the modes that resonate in the laser cavity.

### BRIEF SUMMARY OF THE INVENTION

These and other limitations are overcome by embodiments of the invention which relate to short length gain regions in semiconductor lasers. In Fabry-Perot lasers and other laser types, it is often desirable to have short laser cavity lengths. The cavity length has an impact on both power and laser modes. In conventional lasers, the cavity length is related to the cleaving process. In other words, the length of the laser cavity is typically the same as the length of the laser bar. As a result, the length of the laser cavity cannot be precisely controlled during the cleaving process. Further, there are limitations on how short of a laser can be effectively cleaved.

Embodiments of the invention produce short length cavities that are independent of the cleaving process. As a result, the cleaving process can be made independent of the power consumption and becomes less of a factor for the wavelengths that can be emitted by the laser. In one embodiment, an active region is formed on a substrate. After the active region is formed, the active region is selectively etched. The active region is etched such that only the ultimate laser cavities remain. The length of the cavities that are not etched can be controlled more precisely than they can when cleaved. A transparent layer is then grown in the etched portions of the active region. Finally, the top layers of the laser are formed.

After the laser is formed, the cleaving process may then be performed. Because the etching process was used to form the active regions of the individual lasers, cleavage occurs in the transparent layer that was grown in the etched portions of the active region. This enables a laser bar to be formed where the length of the active region is no longer dependent on the cleaving process, but is dependent on the more controllable and precise etching process. In addition, current requirements for the laser can be reduced because the active region is shorter that the overall length of the laser bar.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1A illustrates a top view of a wafer on which edge emitting lasers have been grown;

FIG. 1B illustrates a side view of the wafer in FIG. 1A and illustrates examples of the layers grown in the wafer;

FIG. 1C illustrates an example of a laser that is produced from the wafer illustrated in FIGS. 1A and 1B;

FIG. 2 illustrates a side view of a wafer in accordance with an embodiment of the invention;

FIG. 3 illustrates an embodiment of a cleavage plane in accordance with embodiments of the invention;

FIG. 4 illustrates one embodiment of an edge emitting laser in accordance with embodiments of the invention;

FIG. 5 illustrates an exemplary method for manufacturing edge emitting lasers with a short gain region;

FIG. 6 illustrates a graph that plots the differential efficiency of a laser as a function of the length of the pumped active region and illustrates the effects of coatings with different reflectivities; and

FIG. 7 illustrates a graph that plots the threshold current of a laser as a function of the length of the pumped active region and also illustrates the effects of coatings with different reflectivities.

### DETAILED DESCRIPTION OF THE PREFERRED EMBODIMENTS

Embodiments of the invention relate to short length lasers. More particularly, embodiments of the invention relate to systems and methods for manufacturing edge emitting lasers that have an active region or gain region that is independent of both the laser length and the cleaving process. Current and power requirements can be reduced as the length of the active region is shortened. The resulting lasers can have lower threshold currents and higher differential efficiencies as the area requiring pumping is reduced.

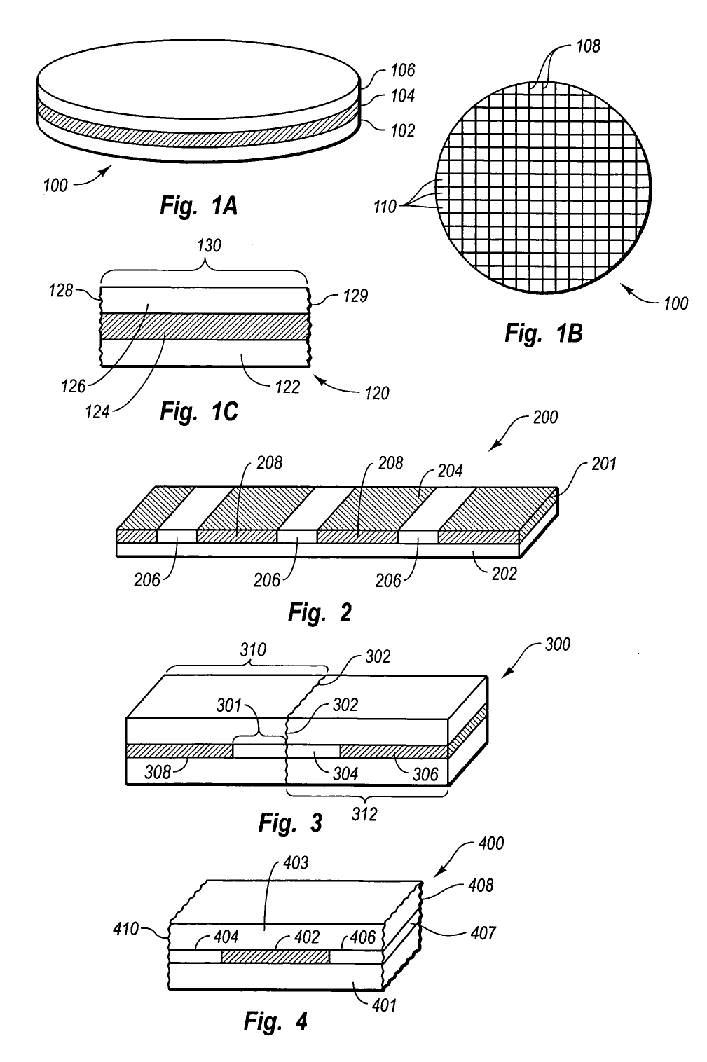

FIG. 1A illustrates a wafer 100 that includes, in this example, edge emitting lasers 110. The wafer 100 and more particularly, the edge emitting lasers 110, have been grown using conventional methods. FIG. 1B illustrates examples of the structure of an edge emitting laser. Generally, the active layer 104 is grown on a lower cladding layer 102 that is typically grown on a substrate. An upper layer 106 is then grown on the active layer 104 such that the active layer is sandwiched by the layers 102 and 106.

The materials used to form the layers are selected such that the layers 102 and 106 tend to confine the light to the active layer because that is where recombination and stimulated emission preferably occur. One of skill in the art can appreciate that a typical edge emitting layer can have other layers that are generalized by the layers 102 and 106. The active layer 104, for example, can be sandwiched by confinement layers which are in turn sandwiched between the layers 102 and 106. In addition, the active layer 104 may include quantum wells and barrier layers separating the quantum wells.

The lines 108 represent cleavage planes that ultimately form the facets of the edge emitting lasers in one embodiment. The edge emitting laser 120 shown in FIG. 1C illustrates this principle. The laser 120 includes an active layer 124 that is bounded by cladding layers 122 and 126 as previously described. The laser 120 has a length 130 that represents a length of the cavity. The laser 120 also has cleaved facets 128 and 129 at opposing ends of the laser 120. The cleaved facets 128 and 129 are reflective and reflect light within the laser cavity. One or both of the facets may be coated with a reflective coating to enhance the reflectivity of the facet. The back facet typically has more reflectivity than the front facet in order to emit more light at the front facet. As the light reflects through the laser cavity, some of the light escapes as laser light.

As previously described, the relatively long length of conventional laser cavities is related to physical limitations in cleaving the wafer. In other words, the length of the laser cavity is in part related to the inability to cleave the wafer such that the laser cavities are relatively shorter. This is a disadvantage in conventional lasers because a shorter cavity can result in a more narrow spectral width. Thus, producing a Fabry-Perot laser with a short cavity length and narrow spectral width would be advantageous.

Embodiments of the invention effectively shorten the laser cavity using selective area regrowth. FIG. 2 illustrates selective area regrowth in one embodiment of the invention. FIG. 2 illustrates a wafer of edge emitting lasers before the top cladding layers are formed.

In this embodiment, the active layer 201 is formed on the layer 202. Before the upper semiconductor layers are formed on the active layer 201, a mask is formed such that the active layer 201 can be selectively etched. In other words, portions of the active layer are removed. The layer 202 can serve as a natural stop to the etching process, which can be either isotropic or anisotropic in nature.

After the active layer 201 is etched, active portions 208 and etched portions 206 remain in the active layer. Next, the etched portions 206 are regrown with another semiconductor material. Typically, this semiconductor material that is regrown in the etched portions 206 is transparent to the laser light and/or wavelength of interest for the laser 200. After the etched portions 206 are regrown, the active layer includes both active regions and inactive regions. Next, the upper layers of the edge emitting layers are then formed or grown on the active layer. The selective area regrowth enables the length of the active region for individual lasers to be controlled more precisely than with cleaving.

FIG. 3 illustrates a cleavage plane in a portion of a wafer that includes edge emitting lasers. In a semiconductor wafer, cleavage planes identify locations where the wafer is cleaved to separate out the individual edge emitting lasers or to separate rows of edge emitting lasers. In the example of FIG. 3, the cleavage plane 302 is where the wafer 300 is cleaved to separate out the individual lasers 310 and 312. Cleaving the wafer produces the cleaved facets shown in FIG. 1C, for example.

FIG. 3 also illustrates that the cleavage plane 302 occurs within an inactive region 304 of the wafer 300 where the active layer has been regrown with a material that is different from the material in the active regions 306 and 308. The distance 301 from the cleavage plane 302 to the active region 308 of the laser 310 results in an edge emitting laser with a shorter gain cavity even though the laser itself may not be any shorter in overall length.

In other words, there is a limit as to how small a bar can be cleaved and this limit had a corresponding impact on the length of the laser cavity as previously described. FIG. 3 illustrates that the length of a cleaved laser is independent of the laser cavity length. The length of the cavity and more specifically the active region can be more precisely controlled during the fabrication process of the edge emitting lasers. The length of the active region is also independent of the cleaving process because the cleaving process no longer occurs in the active region.

FIG. 4 illustrates a perspective view of an edge emitting laser 400 after the cleaving process. The laser 400 includes a back facet 410 and a front facet 408. The facets were formed by cleaving the wafer. As described above, the active region has been selectively regrown with a material that is transparent to the laser light. The regrown material is inactive. Thus, the laser cavity 402 does not extend from the back facet 410 to the front facet 408, but is shorter in this example. The active region 402 is bounded by the inactive regions 404 and 406. The cleavage planes were selected such that cleavage of the wafer or of the laser bars occurred in the material 404 and 406.

The selected regrowth material used in the inactive regions 404 and 406 enable the laser cavity, defined in one embodiment by the length of the active region 402, to be shorter than what can be conventionally cleaved. The back facet 410 and the front facet 408 are formed during the cleavage process. The facets 410 and 408 can be coated to increase or decrease reflectivity as needed.

Generally stated, the active layer 407 may refer to the layers or materials sandwiched between the lower layers 401 and the upper layers 403. In FIG. 4, the active region 402 and the inactive regions 404 and 406 are a waveguide for the laser light and are included in the active layer 407. The active region 402 is a portion of the active layer 407.

Because stimulated emission occurs in the active region 402, only the active region 402 requires a pumping current. In other words, the area that requires pumping in the laser 400 corresponds to the area of the active region 402. The area of the inactive regions 404 and 406 does not need to be pumped as stimulated emission does not typically occur in these areas. The reduced area requires less current and corresponds to a reduction in power requirements of the laser 400.

Although FIG. 4 illustrates that for the laser 400, the active region 402 is bounded by the inactive regions 404 and 406, one of skill in the art can appreciate that the active layer can be selectively regrown in other configurations. FIG. 4 illustrates two boundaries between the active region and the inactive regions of the active layer. In another embodiment, only one boundary is present in the active layer of a particular laser.

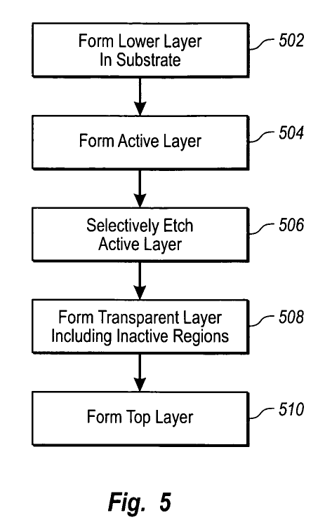

FIG. 5 illustrates an exemplary method for fabricating an edge emitting laser with a short gain region. A lower layer is typically formed (502) on a semiconductor wafer. The lower layer can include multiple semiconductor materials or various layers. The lower layer may include a substrate or may be formed on the substrate. After the lower layer is formed, the active layer is formed (504). One of skill in the art can appreciate that the active layer can be a block material or formed, in one embodiment, using quantum wells.

After the active layer is formed, the active layer is selectively etched (506). Selectively etching the active layer can include forming a mask layer to protect certain portions of the active layer from being etched. The protected portions correspond to the active regions of the resulting lasers. After the etching process, a new layer is formed in the etched portions. In other words, the etched portions of the active layer are regrown with a material that is typically different from the active region. In other words, the inactive regions of the active layer are grown in the etched portions of the active layer. After the active layer is completed, the top layer is formed (510). One of skill in the art can appreciate that the top layer may include various semiconductor layers. In addition, a grating can be formed in the top layer(s) as well to fabricate DFB or DBR lasers.

The active layer is grown through a selective area growth process. As previously described, this enables the length of the active region to be controlled by the selective growth process instead of the cleaving process. In an edge emitting laser, the active region of the active layer is pumped with current. Because the active region is shorter, less current is required to pump the active region. This can reduce threshold currents and can also have an impact on temperature. In one embodiment, only a portion of the active layer (the active region) is pumped and the remaining portion of the active layer (the regrown portion or the inactive regions) is made transparent by a band-gap shift during the regrowth process. This enables the laser to have a short pumped segment while still providing a waveguide for the entire length of the laser.

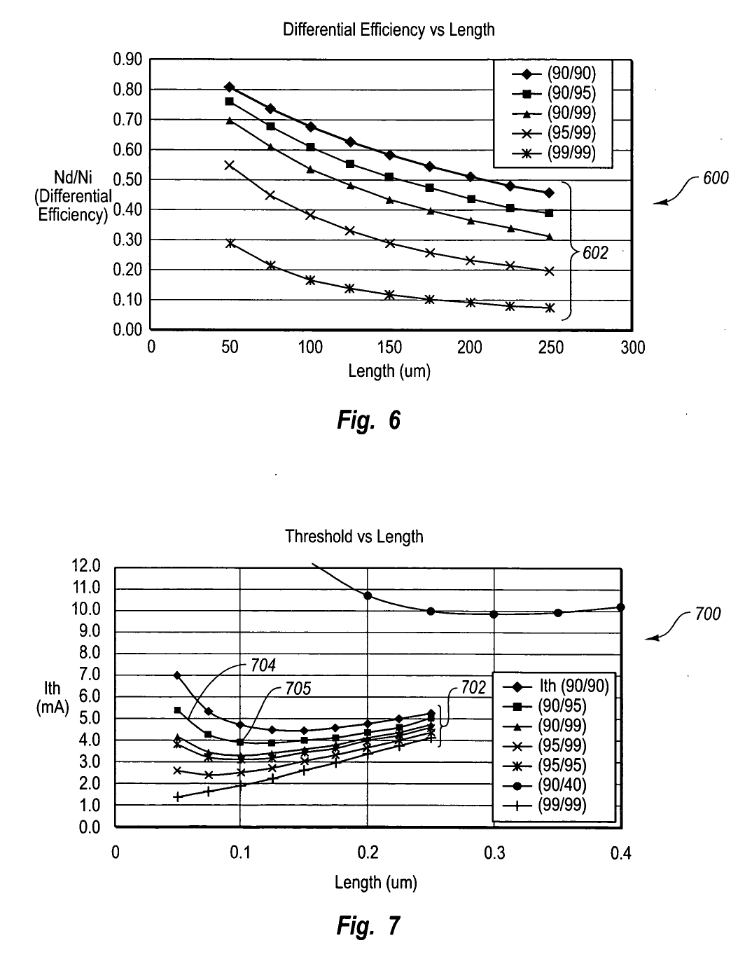

FIG. 6 illustrates a graph that plots the differential efficiency of a laser as a function of the pumped length of the active region. In one embodiment, the differential efficiency corresponds to light out versus current in. The plot 600 includes several curves 602. Each curve corresponds to coatings on the facets that provide different percentage reflectivities. The plot 600 illustrates that higher efficiencies are achieved for shorter pumped lengths.

Embodiments of the invention overcome dependence of the pumped length on the cleaving process and make the length of the pumped active region and the overall length of the cleaved laser independent variables.

The length of the pumped active region also has an impact on the threshold current of the laser. FIG. 7 illustrates a plot 700 that plots the threshold current as a function of pumped length. The length axis illustrated in FIG. 7 corresponds to the pumped length and not the length of the laser bar because the two lengths are independent parameters according to embodiments of the invention. Each of the curves 702 corresponds to different reflectivity coatings.

FIG. 7 illustrates that as the length of the pumped active region becomes shorter, the threshold current becomes lower. For the curve 704, for example, the point 705 appears to be the minimum point where the length of the pumped region and the laser's threshold current is lowest. As the length of the pumped region continues to shorten, it becomes more difficult to provide sufficient carriers for lasing action. However, selectively growing the active layer can reduce the pumped length of the active region, which has a corresponding benefit in terms of at least threshold current and differential efficiency.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for fabricating an edge emitting laser, the method comprising:
forming a first layer on a substrate;
forming an active layer over the substrate;
selectively etching the active layer to create etched portions in the active layer;
forming an inactive material in the etched portions of the active layer such that the active layer includes one or more active regions and one or more inactive regions; and
forming a top layer on the active layer.

2. A method as defined in claim 1, wherein forming an active layer further comprises forming quantum wells.

3. A method as defined in claim 1, wherein selectively etching the active layer to create etched portions in the active layer further comprises masking the active layer, wherein the first layer is an etch stop.

4. A method as defined in claim 1, wherein forming an inactive material further comprises establishing a band-gap shift between the one or more active regions and the one or more inactive regions.

5. A method as defined in claim 1, further comprising cleaving the laser such that a cleavage plane passes through one or more inactive regions of the active layer.

6. A method as defined in claim 1, further comprising coating facets at opposing ends of the active region with at least one of an antireflective coating and a reflective coating.

7. A method as defined in claim 1, further comprising selecting a length of the one or more active regions.

8. An edge emitting laser comprising:
a lower layer formed on a substrate;
an active layer formed on the lower layer, the active layer including an active region and one or more inactive regions; and
an upper layer formed on the active layer.

9. The edge emitting laser defined in claim 8, wherein the one or more active regions include a bulk material.

10. The edge emitting laser defined in claim 3, wherein the one or more active regions include one or more quantum wells.

11. The edge emitting laser defined in claim 8, wherein the one or more inactive regions are formed from a material that is transparent to light emitted by the one or more active regions.

12. The edge emitting laser defined in claim 8, further comprising a contact layer formed on the upper layer, the contact layer configured to provide current to the active region.

13. The edge emitting laser defined in claim 8, wherein a facet is located in the one or more inactive regions such that a length of the active region is unrelated to a length of the active layer.

14. The edge emitting laser defined in claim 8, wherein the one or more inactive regions have a band-gap shift from the active region.

15. The edge emitting laser defined in claim 8, further comprising confinement layers that sandwich the active layer, wherein the confinement layers are located between the lower layer and the upper layer.

16. A method for forming a laser such that a current threshold of the laser is independent of a length of the laser, the method comprising:
forming a lower layer of the laser on a substrate;
forming an active layer on the lower layer;
forming a mask layer on the active layer to define portions of the active layer to be an active region;
etching portions in the active layer such that the active region is not etched;
forming one or more inactive regions in the etched portions of the active layer, wherein the one or more inactive regions form boundaries with the active region; and
forming an upper layer on the active layer.

17. The method of claim 16, further comprising forming a mask layer to define a length of the active region.

18. The method of claim 16, further comprising cleaving the laser such that cleavage planes occur in the one or more inactive regions.

19. The method of claim 16, further comprising forming the one or more inactive regions to have a band gap shift relative to the active region such that the one or more inactive regions of the active layer are transparent to light emitted in the active region.

20. The method of claim 16, further comprising coating facets with at least one of a antireflective coating and a highly reflective coatings.
